(19) United States
(12) Patent Application Publication
(10) Pub. No.: US 2025/0022917 A1
(43) Pub. Date: Jan. 16, 2025

(54) SEMICONDUCTOR DEVICE AND METHOD FOR MANUFACTURING THE SAME

(71) Applicants: Hyundai Motor Company, Seoul (KR); Kia Corporation, Seoul (KR)

(72) Inventors: NackYong Joo, Suwon-si (KR); Dae Hwan Chun, Suwon-si (KR); Jungyeop Hong, Seoul (KR); Taehyun Kim, Suwon-si (KR); Youngkyun Jung, Seoul (KR); Junghee Park, Suwon-si (KR)

(21) Appl. No.: 18/524,544

(22) Filed: Nov. 30, 2023

(30) Foreign Application Priority Data
Jul. 13, 2023 (KR) 10-2023-0090823

(51) Int. Cl. H01L 29/08; H01L 21/04; H01L 29/06; H01L 29/16; H01L 29/66; H01L 29/78

(52) U.S. Cl. CPC H01L 29/0869; H01L 21/047; H01L 29/063; H01L 29/1608; H01L 29/66068; H01L 29/7813

(57) ABSTRACT

An embodiment semiconductor device includes an N− type layer having a trench therein, a P type region within the N− type layer, an N+ type region within the P type region, a gate electrode within the trench including a first gate electrode having an upper surface lower than an upper surface of the P type region and a second gate electrode having an upper surface lower than the upper surface of the first gate electrode, and source and drain electrodes insulated from the gate electrode, wherein the N+ type region includes a first N+ type region on a side of the first gate electrode and having a lower surface lower than the upper surface of the first gate electrode and a second N+ type region on a side of the second gate electrode and having a lower surface lower than the lower surface of the first N+ type region.

### CROSS-REFERENCE TO RELATED APPLICATIONS

This application claims the benefit of Korean Patent Application No. 10-2023-0090823, filed on Jul. 13, 2023, which application is hereby incorporated herein by reference.

### TECHNICAL FIELD

The present disclosure relates to a semiconductor device and a method of manufacturing the same.

### BACKGROUND

Semiconductor devices (MOSFET, JFET, MESFET, IGBT, etc.) are three-terminal devices that can conduct current through control of the gate terminal. In particular, power semiconductor devices for switching require high voltage and large current.

Semiconductor devices have different electrical characteristics depending on their structure, and appropriate devices are used depending on the application field. However, they commonly require high current density, low turn-on voltage, high breakdown voltage, low leakage current, and fast switching speed, and various structures have been proposed to simultaneously satisfy the above requirements.

However, the above electrical characteristics form a trade-off relationship, and structures for improving one or more characteristics while maintaining other characteristics by weakening the trade-off relationship are continuously being researched.

In particular, MOSFETs and IGBTs, which are mainly used as transistors in power conversion systems, are manufactured with a gate structure in the form of a trench as a method to reduce on-resistance, and even in the trench gate structure, the characteristics (current density and cell pitch) are improved through a buried gate where the gate polysilicon (Poly-Si) is not exposed to the surface.

### SUMMARY

One embodiment provides a semiconductor device and a method of manufacturing the same in which, by removing a gate protruding portion when forming a buried gate, defects caused by the possibility of a gate-source short circuit are improved, and the problem of channel non-formation due to etch process deviation (over-etching) is solved, thereby increasing a device yield, not requiring a development of new process technology because additional processes are not required, and not increasing process costs.

According to one embodiment, a semiconductor device includes an N+ type substrate, an N− type layer disposed on the N+ type substrate in a first direction and having a trench opening upward in the first direction, a P type region disposed within the N− type layer and disposed on a side of the trench, an N+ type region disposed within the P type region and disposed on a side of the trench, a gate electrode disposed within the trench, and a source electrode and a drain electrode insulated from the gate electrode, wherein the gate electrode includes a first gate electrode whose upper surface is disposed under the upper surface of the P type region in the first direction and a second gate electrode whose upper surface is disposed under the upper surface of the first gate electrode in the first direction, and wherein the N+ type region includes a first N+ type region disposed on a side of the first gate electrode and having a lower surface disposed under the upper surface of the first gate electrode in the first direction and a second N+ type region disposed on a side of the second gate electrode and having a lower surface disposed under a lower surface of the first N+ type region in the first direction.

The second N+ type region may have a lower surface substantially at the same position as the upper surface of the second gate electrode in the first direction.

The second N+ type region may have a lower surface disposed under the upper surface of the second gate electrode in the first direction.

The trench may have side surfaces extending in a second direction perpendicular to the first direction and facing each other in a third direction perpendicular to the first direction and different from the second direction.

The second N+ type region may have an upper portion of the second N+ type region and a lower portion of the second N+ type region which have different maximum lengths in the third direction from one side of the trench.

The upper portion of the second N+ type region may have a greater maximum length in the third direction from one side of the trench than the lower portion of the second N+ type region.

The upper portion of the second N+ type region may be disposed on the lower portion of the second N+ type region in the first direction.

The gate electrode may further include a third gate electrode whose upper surface is substantially at the same position in the first direction as the upper surface of the P type region.

The N+ type region may further include a third N+ type region disposed on a side of the third gate electrode and having a lower surface disposed under the upper surface of the first gate electrode in the first direction.

The N− type layer may further include a P type shield region surrounding the lower surface and both edges of the trench.

The N− type layer may further include an asymmetric P type region that surrounds one edge and one side of the trench and is connected to the P type region.

The asymmetric P type region may surround a portion of the lower surface of the trench.

The asymmetric P type region may not surround one edge or the other side of the trench.

According to another embodiment, a semiconductor device includes an N− type layer having a trench opening upward in the first direction, a P type region disposed within the N− type layer and disposed on the side of the trench, an N+ type region disposed within the P type region and disposed on the side of the trench, a gate electrode disposed within the trench, an emitter electrode and a collector electrode insulated from the gate electrode, and a P+ type layer disposed between the N− type layer and the collector electrode, wherein the gate electrode includes a first gate electrode whose upper surface is disposed under the upper surface of the P type region in the first direction and a second gate electrode whose upper surface is disposed under the upper surface of the first gate electrode in the first direction, and wherein the N+ type region includes a first N+ type region disposed on a side of the first gate electrode and having a lower surface disposed under the upper surface of the first gate electrode in the first direction and a second N+ type region disposed on a side of the second gate electrode and having a lower surface disposed under a lower surface of the first N+ type region in the first direction.

According to another embodiment, a method of manufacturing a semiconductor device includes forming an N− type layer on a first direction of an N− type substrate, forming a P type region in the N− type layer, etching the N− type layer to penetrate the P type region to form a trench, filling the trench with a preliminary gate electrode layer, over-etching the preliminary gate electrode layer until the upper surface of the preliminary gate electrode layer is disposed under the upper surface of the P type region in the first direction to form a gate electrode and to expose a portion of the side surface of the trench, implanting N type ions into the upper surface of the P type region disposed adjacent to the trench and the exposed side of the trench for forming an N+ type region, and forming a source electrode and a drain electrode to be insulated from the gate electrode.

The forming of the N+ type region may be performed after forming a hardmask exposing the upper surface of the P type region disposed adjacent to the trench on the P type region.

The step of forming the N+ type region may use a tilt ion implantation method.

The semiconductor device according to one embodiment improves defects caused by the possibility of a gate-source short circuit by removing the gate protrusion when forming a buried gate and solves the problem of channel non-formation due to etch process deviation (over-etching), thereby increasing a device yield, not requiring a development of new process technology because additional processes are not required, and not increasing process costs.

### BRIEF DESCRIPTION OF THE DRAWINGS

FIG. 1 is a cross-sectional view of a semiconductor device according to one embodiment.

FIG. 2 is a cross-sectional view of a semiconductor device according to another embodiment.

FIG. 3 is a cross-sectional view of a semiconductor device according to another embodiment.

FIG. 4 is a cross-sectional view of a semiconductor device according to another embodiment.

FIGS. 5 to 8 are cross-sectional views showing intermediate steps in a method of manufacturing a semiconductor device according to one embodiment.

### DETAILED DESCRIPTION OF ILLUSTRATIVE EMBODIMENTS

The advantages, features, and aspects to be described hereinafter will become apparent from the following description of the embodiments with reference to the accompanying drawings, which is set forth hereinafter. However, the embodiments should not be construed as being limited to the embodiments set forth herein. Although not specifically defined, all of the terms including the technical and scientific terms used herein have meanings understood by ordinary persons skilled in the art. The terms defined in a generally used dictionary may not be interpreted ideally or exaggeratedly unless clearly defined. In addition, unless explicitly described to the contrary, the word “comprise”, and variations such as “comprises” or “comprising”, will be understood to imply the inclusion of stated elements but not the exclusion of any other elements.

Further, the singular includes the plural unless mentioned otherwise.

In the drawings, the thickness of layers, films, panels, regions, etc. are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

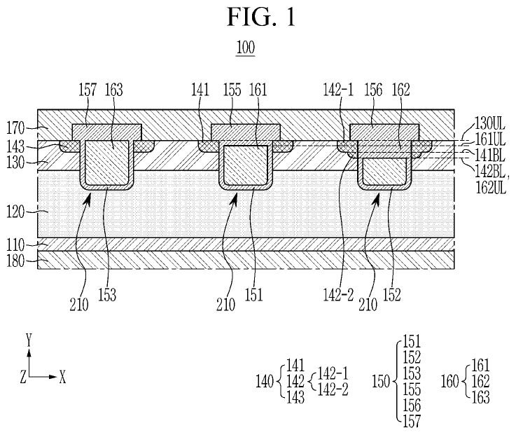

FIG. 1 is a view illustrating a cross section of a semiconductor device 100 according to one embodiment. FIG. 1 is a cross-sectional view cut generally in a direction perpendicular to the direction in which a gate electrode 160 extends.

For example, the direction in which the gate electrode 160 extends is a Z direction, and directions generally perpendicular to the Z direction may be the X and Y directions. Hereinafter, in the present specification, the X direction may be referred to as a width direction, the Y direction may be referred to as an upper direction, a direction opposite to the Y direction may be referred to as a lower direction, and the Z direction may be referred to as the extension direction. Additionally, in this specification, the Y direction may be referred to as a first direction, the Z direction may be referred to as a second direction, and the X direction may be referred to as a third direction.

The semiconductor device 100 includes an N+ type substrate 110, an N− type layer 120, a P type region 130, a gate electrode 160, a source electrode 170, and a drain electrode 180.

The N+ type substrate 110 may have a first surface and a second surface facing each other in the Y direction. For example, the first surface of the N+ type substrate 110 may be disposed on the upper portion in the Y direction, and the second surface may be disposed at the lower portion in the Y direction. As an example, the N+ type substrate 110 may be an N+ type silicon carbide (SiC) substrate.

The N− type layer 120 is located at the upper portion, that is, on the first surface, of the N+ type substrate 110 in the Y direction. The N− type layer 120 may be formed by epitaxial growth or implantation of N− type ions.

The N− type layer 120 has a trench 210. The trench 210 is opened on a side opposite to the side where the N− type layer 120 faces the N+ type substrate 110. That is, the trench 210 opens upward in the Y direction in FIG. 1.

In the trench 210, an inner surface, which is generally horizontal to the surface of the N− type layer 120 but has a step of a predetermined depth downward in the Y direction and a width in the X direction, is defined as a bottom surface of the trench 210, other inner surfaces, which connect the surface of the N− type layer 120 and the lower surface of the trench 210, have a height in the Y direction, and face each other in the X direction, may be defined as side surfaces of the trench 210, and a line where the lower surface of the trench 210 meets the side surfaces of the trench 210 may be defined as an edge (corner) of the trench 210.

The P type region 130 is located inside the N− type layer 120 and positioned adjacent to the side surfaces of the trench 210. For example, the P type region 130 may be located on the upper direction (Y direction) surface of the N− type layer 120. The P type region 130 may be a region where P type ions are implanted into the N− type layer 120.

The N+ type region 140 may be located in the P type region 130 and positioned adjacent to the side surfaces of the trench 210. For example, the N+ type region 140 may be located on the upper direction (Y direction) surface of the P type region 130. For example, the N− type layer 120, the P type region 130, and the N+ type region 140 may be sequentially disposed at the side surfaces of the trench 210 in the upper direction (Y direction). The ion implantation into the N+ type region 140 may be performed at a higher concentration than that into the N− type layer 120.

Inside the trench 210, a gate insulation layer 150 may be disposed, and on the gate insulation layer 150, a gate electrode 160 is disposed. Herein, the gate insulation layer 150 disposed between the trench 210 and the gate electrode 160 may be referred to as first to third lower gate insulation layers 151, 152, and 153.

The gate insulation layer 150 may be disposed on the gate electrode 160 on top of the trench 210. Herein, the gate insulation layer 150 on the gate electrode 160 may be referred to as first to third upper gate insulation layers 155, 156, and 157. The first to third upper gate insulation layers 155, 156, and 157 may be disposed on the N+ type region 140, on the P type region 130, or on the N− type layer 120.

The gate electrode 160 may include polysilicon or metal. The gate insulation layer 150 may include SiO₂, Si₃N₄, or a combination thereof.

The source electrode 170 is disposed on the N− type layer 120. The source electrode 170 may be disposed on the P type region 130, the N+ type region 140, and/or the N− type layer 120. The source electrode 170 is insulated from the gate electrode 160 by the first to third upper gate insulation layers 155, 156, and 157. The source electrode 170 may include Cr, Pt, Pd, Au, Ni, Ag, Cu, Al, Mo, In, Ti, polycrystalline Si, an oxide thereof, a nitride thereof, or an alloy thereof. Additionally, the source electrode 170 includes a multilayer electrode structure in which different metal films are stacked, for example, Pt/Au, Pt/Al, Pd/Au, Pd/Al, or Pt/Ti/Au and Pd/Ti/Au.

The drain electrode 180 is disposed under the N+ type substrate 110 in the Y direction. The drain electrode 180 may be disposed on the N− type layer 120 apart from the source electrode 170. The drain electrode 180 may include Cr, Pt, Pd, Au, Ni, Ag, Cu, Al, Mo, In, Ti, polycrystalline Si, an oxide thereof, a nitride thereof, or an alloy thereof. Additionally, the drain electrode 180 may include a multilayer electrode structure in which different metal films are stacked, for example, Ti/Au or Ti/Al.

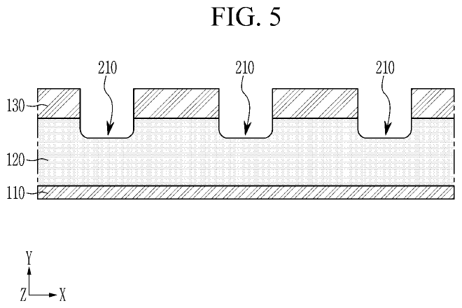

On the other hand, in order to form this buried gate electrode structure, as shown in FIGS. 5 to 8, after filling a preliminary gate electrode layer 160P in the trench 210, the preliminary gate electrode layer 160P protruding above the trench 210 should be removed. Herein, a time-etching method should be used to adjust an etching time and an etch rate based on a thickness of the upward-protruded preliminary gate electrode layer 160P, wherein the etching of the preliminary gate electrode layer 160P should meet a condition of Y direction position (level) of the lower surface of the N+ type region 140<Y direction position (level) of the upper surface of the gate electrode 160<Y direction position (level) of the upper surface of the N+ type region 140.

For example, when the preliminary gate electrode layer 160P remains on the upper surface of the gate electrode 160 and forms protrusions, resulting in a condition of Y direction position (level) of the upper surface of the gate electrode 160>Y direction position (level) of the upper surface of the N+ type region 140, the gate electrode 160 and the source electrode 170 may be short-circuited.

In addition, when the preliminary gate electrode layer 160P is over-etched, resulting in a condition of Y direction position (level) of the lower surface of the N+ type region 140>Y direction position (level) of the upper surface of the gate electrode 160, a channel may not be formed, failing in operating the semiconductor device 100.

However, since the N+ type region 140 in general has a very thin depth of about 0.2 μm to about 0.3 μm, and the preliminary gate electrode layer 160P has no constant thickness, it is difficult to etch the preliminary gate electrode layer 160P to satisfy the aforementioned condition through the time-etching method. In addition, a yield may be reduced due to an etching rate difference depending on a wafer position.

Accordingly, the semiconductor device 100 according to one embodiment, as described in FIGS. 5 to 8, may be prevented from a short circuit between the gate electrode 160 and the source electrode 170 by intentionally over-etching the preliminary gate electrode layer 160P when the buried gate structure is formed, so that no protruding portion derived from the preliminary gate electrode layer 160P may remain on the upper surface of the gate electrode 160.

In addition, the channel non-formation problem may be solved by implanting N type ions into a portion of the side surface of the trench 210 which is exposed by intentionally over etching the preliminary gate electrode layer 160P, so that the Y direction position (level) of the bottom surface of the N+ type region 140 and the Y direction position (level) of the upper surface of the gate electrode 160 may be substantially aligned at the same position.

According to the semiconductor device 100 of one embodiment, a yield of the semiconductor device 100 is increased, a process cost is not increased due to no additional process, and the ion implantation process and the epi process are used and thus require no development of new process technology.

Accordingly, the gate electrode 160 of the semiconductor device 100 according to one embodiment may include a first gate electrode 161, of which the upper surface 161UL is located lower than the upper surface of the N+ type region 140 or the upper surface 130UL of the P type region 130 in the Y direction.

In addition, the N+ type region 140 may include a first N+ type region 141, which is disposed on the side surface of the first gate electrode 161, and the lower surface 141BL of the first N+ type region 141 is located lower than the upper surface 161UL of the first gate electrode 161 in the Y direction. Herein, the upper surface of the first N+ type region 141 may be located lower than the upper surface 161UL of the first gate electrode 161 in the Y direction.

In other words, the condition of Y direction position (level) of the lower surface 141BL of the first N+ type region 141<Y direction position (level) of the upper surface 161UL of the first gate electrode 161<Y direction position (level) of the upper surface of the first N+ type region 141 is satisfied.

In addition, the gate electrode 160 of the semiconductor device 100 according to one embodiment may further include a second gate electrode 162, wherein the upper surface 162UL of the second gate electrode 162 is located lower than the upper surface 161UL of the first gate electrode 161 in the Y direction. In other words, as the preliminary gate electrode layer 160P is intentionally over-etched, the second gate electrode 162 is more over-etched than the first gate electrode 161.

In addition, the N+ type region 140 is positioned at the side surface of the second gate electrode 162 and may further include a second N+ type region 142, of which the lower surface 142BL is located lower than the lower surface 141BL of the first N+ type region 141. Herein, the lower surface 142BL of the second N+ type region 142 may be located substantially at the same position as the upper surface 162UL of the second gate electrode 162 in the Y direction or lower than the upper surface 162UL of the second gate electrode 162 in the Y direction.

In other words, the condition of Y direction position (level) of the lower surface 142BL of the second N+ type region 142<Y direction position (level) of upper surface 162UL of the second gate electrode 162<Y direction position (level) of the upper surface of the second N+ type region 142 may be satisfied.

The second N+ type region 142 may have an upper portion 142-1 and a lower portion 142-2.

As described in FIGS. 5 to 8 which will be described later, as the second N+ type region 142 may be formed by intentionally over-etching the preliminary gate electrode layer 160P to expose a portion of the side surface of the trench 210 and then implanting N type ions into the upper surface 130UL of the P type region 130 positioned adjacent to the trench 210 and into the exposed side surface of the trench 210, the upper portion 142-1 of the second N+ type region 142 is formed in the region where the ions are implanted into the upper surface 130UL of the P type region 130, while a lower portion 142-2 of the second N+ type region 142 is formed in the region where the ions are implanted into the exposed side surface of the trench 210.

Accordingly, the upper portion 142-1 of the second N+ type region 142 may be located higher than the lower portion 142-2 of the second N+ type region 142 in the Y direction, for example, the upper portion 142-1 of the second N+ type region 142 may be positioned on the surface of the N− type layer 120 in the Y direction. In addition, since the upper portion 142-1 of the second N+ type region 142 is formed in the same process as the method of forming the first N+ type region 141, the upper surface of the upper portion 142-1 of the second N+ type region 142 may have substantially the same Y direction position as that of the upper surface of the first N+ type region 141, while the lower surface of the upper portion 142-1 of the second N+ type region 142 may have substantially the same Y direction position as that of the lower surface 141BL of the first N+ type region 141.

In addition, the upper and lower portions 142-1 and 142-2 of the second N+ type region 142 may have a different maximum length in the x direction from one side surface, that is, a different X direction width, for example, the upper portion 142-1 of the second N+ type region 142 may have a larger X direction maximum length than the lower portion 142-2 of the second N+ type region 142 from one side surface of the trench 210. The reason is that the X direction maximum length of the upper portion 142-1 of the second N+ type region 142 is determined by the opening with the X direction length exposed by the hardmask 220, but the X direction maximum length of the lower portion 142-2 of the second N+ type region 142 is determined by an ion implantable distance from the exposed side surface of the trench 210.

In addition, the gate electrode 160 of the semiconductor device 100 according to one embodiment may further include substantially the same third gate electrode 163 as the upper surface of the P type region 130 or the upper surface of the N+ type region 140 in the Y direction. In other words, since the preliminary gate electrode layer 160P has the protruding portions, which are etched, the third gate electrode 163 is not over-etched, while the first gate electrode 161 or the second gate electrode 162 is over-etched.

In addition, the N+ type region 140 may further include a third N+ type region 143, which is located at the side surface of the third gate electrode 163, wherein the lower surface of the third N+ type region 143 is located lower than the upper surface of the third gate electrode 163 in the Y direction.

In other words, the condition of Y direction position (level) of the lower surface of the third N+ type region 143<Y direction position (level) of the upper surface of the third gate electrode 163≤ Y direction position (level) of the upper surface of the third N+ type region 143 may be satisfied.

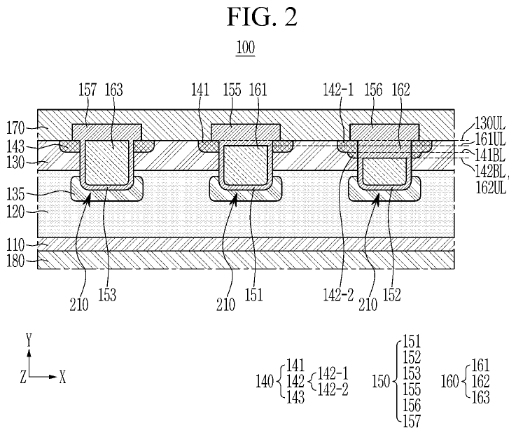

Hereinafter, the semiconductor device 100 according to another embodiment will be described with reference to FIG. 2.

FIG. 2 is a cross-sectional view of a semiconductor device 100 according to another embodiment.

Since the embodiment shown in FIG. 2 has many of the same parts as the embodiment shown in FIG. 1, descriptions thereof will be omitted and the differences will be mainly explained.

Referring to FIG. 2, the N− type layer 120 may further include a P type shield region 135 located below the inner lower surface of the trench 210. The P type shield region 135 is a structure for protecting the first to third lower gate insulation layers 151, 152, and 153 of the trench 210.

The P type shield region 135 surrounds the inner lower surface and edges of the trench 210. Herein, the edges of the trench 210 means edges where the lower surface of the trench 210 meets the side surface of the trench 210. The inner edges of the trench 210 are regions where an electric field is the most strongly applied, and the P type shield region 135 may surround the inner edges of the trench 210 to weaken the electric field of the edges.

In addition, the P type shield region 135 surrounds the inner edges of the trench 210 and then may extend to a portion of a height of the inner side surface of the trench 210. However, even though the P type shield region 135 extends to a portion of a height of the inner side surface of the trench 210, it does not extend to the P type region 130.

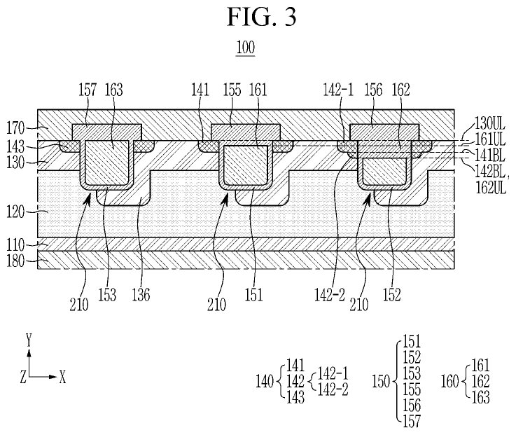

Hereinafter, the semiconductor device 100 according to another embodiment will be described with reference to FIG. 3.

FIG. 3 is a cross-sectional view of a semiconductor device 100 according to another embodiment.

Since the embodiment shown in FIG. 3 has many of the same parts as the embodiment shown in FIG. 1, descriptions thereof will be omitted and the differences will be mainly explained.

Referring to FIG. 3, the N− type layer 120 may further include an asymmetric P type region 136 surrounding one edge and one side surface of the trench 210. Herein, the edge of the trench 210 means an edge where the lower surface of the trench 210 meets the side surface of the trench 210. The edge of the trench 210 is a region where an electric field is the most strongly applied, wherein the asymmetric P type region 136 may surround the inner edge of the trench 210 to weaken the electric field of the inner edge of the trench 210.

In addition, the asymmetric P type region 136 surrounds one edge of the trench 210 and then may extend along one inner side surface of the trench 210 to be connected to the P type region 130. However, the asymmetric P type region 136 may surround a portion of the lower surface of the trench 210 but not surround the other edge and the other side surface of the trench 210.

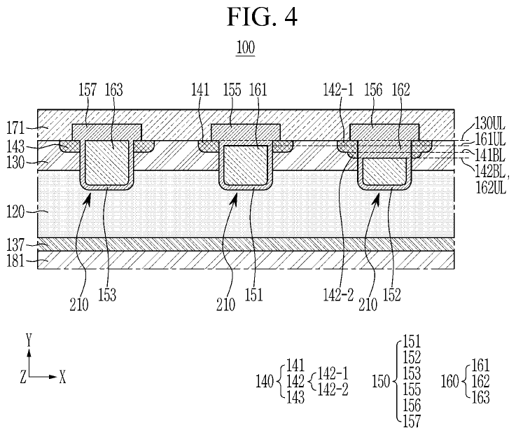

Hereinafter, referring to FIG. 4, the semiconductor device 100 according to another embodiment is described.

FIG. 4 is a cross-sectional view of a semiconductor device 100 according to another embodiment.

FIG. 1 shows that the semiconductor device 100 is a field effect transistor (MOSFET), but FIG. 4 shows that the semiconductor device 100 is an insulation gate bipolar transistor (IGBT).

Since the embodiment shown in FIG. 4 has many of the same parts as the embodiment shown in FIG. 1, descriptions thereof will be omitted and the differences will be mainly explained.

In FIG. 1, the N+ type substrate 110 is disposed under the N− type layer 120 in the Y direction, and the drain electrode 180 is disposed under the N+ type substrate 110 in the Y direction.

In FIG. 4, a P+ type layer 137 is disposed under the N− type layer 120 in the Y direction, and a collector electrode 181 is disposed under the P+ type layer 137 in the Y direction.

In addition, in FIG. 1, the source electrode 170 is disposed on the gate electrode 160 in the Y direction.

In FIG. 4, an emitter electrode 171 is disposed on the gate electrode 160 in the Y direction.

Hereinafter, referring to FIGS. 5 to 8, a method of manufacturing the semiconductor device 100 of one embodiment is described.

FIGS. 5 to 8 are cross-sectional views showing intermediate steps in a method of manufacturing a semiconductor device 100 according to one embodiment. FIG. 5 to FIG. 8 show main processes alone, but orders and methods thereof may be changed according to process environments and conditions.

Referring to FIG. 5, an N− type layer 120 is formed on the N+ type substrate 110 in the Y direction. For example, the N+ type substrate 110 is prepared, and the N− type layer 120 is formed through epitaxial growth on the N+ type substrate 110 in the Y direction.

The P type region 130 is formed on the N− type layer 120. For example, the P type region 130 is formed by implanting ions into an upper region of the N− type layer 120 in the Y direction. Herein, the P type region 130 may be formed through epitaxial growth rather than the ion implantation.

The N− type layer 120 is etched to form a trench 210 through the P type region 130. For example, on the P type region 130, a mask having an opening with a first width is formed. The mask may be, for example, a hardmask including Si₂N₃. The mask may be used to etch the N− type layer 120 and the P type region 130 to have the first width and thus to form the trench 210. A depth (Y direction) of the trench 210, that is, the inner lower surface of the trench 210 may be located through the N+ type region 140 inside the N− type layer 120 and the P type region 130 but may not reach the N+ type substrate 110.

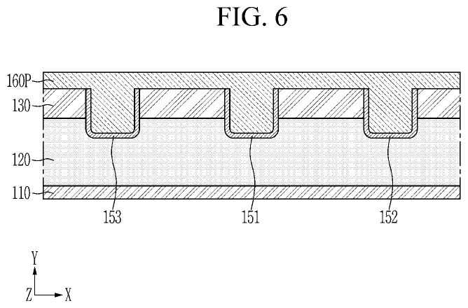

Referring to FIG. 6, after removing the mask, the first to third lower gate insulation layers 151, 152, and 153 are formed inside the trench 210.

Inside the trench 210 where the first to third lower gate insulation layers 151, 152, and 153 are formed, the preliminary gate electrode layer 160P is formed. For example, the preliminary gate electrode layer 160P may be formed by depositing polysilicon inside the trench 210. Herein, the preliminary gate electrode layer 160P may be formed on the N− type layer 120 and the P type region 130 in the Y direction as well as inside the trench 210.

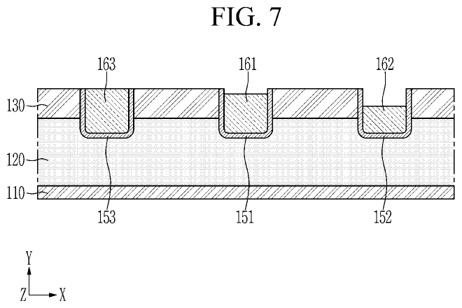

Referring to FIG. 7, the preliminary gate electrode layer 160P protruding from the trench 210 is removed.

Herein, the preliminary gate electrode layer 160P is intentionally over-etched, so that the preliminary gate electrode layer 160P may not remain on the upper surface of the gate electrode 160, to prevent a short circuit of the gate electrode 160 and the source electrode 170.

According to an etching degree of the preliminary gate electrode layer 160P, the first gate electrode 161, of which the upper surface 161UL is located lower than the upper surface 130UL of the P type region 130 in the Y direction, may be formed, and the second gate electrode 162, of which the upper surface 162UL thereof is located lower than the upper surface 161UL of the first gate electrode 161 in the Y direction, may be formed, and the third gate electrode 163 may be formed to have substantially the same upper surface as the upper surface 130UL of the P type region 130 in the Y direction.

The second gate electrode 162 is over-etched more than the first gate electrode 161, but the third gate electrode 163 is not over-etched while the first gate electrode 161 or the second gate electrodes 162 is over-etched, wherein as the preliminary gate electrode layer 160P has a protruding portion, the protruding portion is etched in the third gate electrode 163.

As the first gate electrode 161 and the second gate electrode 162 are over-etched, in the trench 210 in which the first gate electrode 161 and the second gate electrode 162 are formed, a side portion of the trench 210 is exposed.

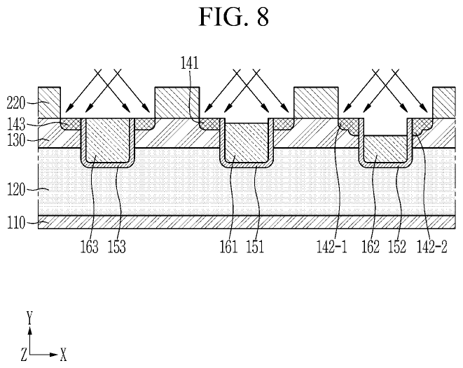

Referring to FIG. 8, N type ions are implanted into the upper surface 130UL of the P type region 130 adjacent to the trench 210 and the exposed side surface of the trench 210 to form the N+ type region 140.

In order to implant the N type ions into the upper surface 130UL of the P type region 130 adjacent to the trench 210, a hardmask 220 exposing the upper surface 130UL of the P type region 130 adjacent to the trench 210 may be exclusively formed on the P type region 130. The hardmask 220 may include, for example, Si₂N₃.

On the other hand, as the first gate electrode 161 is over-etched, a portion of the side surface of the trench 210 is exposed, but the exposed Y direction length is shorter than a Y direction length of a region into which N type ions are implanted on the upper surface 130UL of the P type region 130. Accordingly, the lower surface 141BL of the first N+ type region 141 at the side surface of the first gate electrode 161 may be located lower than the upper surface 161UL of the first gate electrode 161 in the Y direction, which may solve the channel non-formation problem.

On the contrary, as the second gate electrode 162 is further over-etched than the first gate electrode 161, a portion of the side surface of the trench 210 is exposed, wherein the exposed side portion has a larger Y direction length than a region into which N type ions are implanted on the upper surface 130UL of the P type region 130. Accordingly, the lower surface of the upper portion 142-1 of the second N+ type region 142 located at the side surface of the second gate electrode 162 may be located higher in the Y direction than the upper surface 162UL of the second gate electrode 162.

However, since a lower portion 142-2 of the second N+ type region 142 may be formed at the exposed side surface of the trench 210 through the ion implantation, the lower surface of the lower portion 142-2 of the second N+ type region 142 may be located lower in the Y direction than the upper surface 162UL of the second gate electrode 162.

In other words, N type ions may be implanted into a portion of the side surface of the trench 210 exposed by intentionally over-etching the preliminary gate electrode layer 160P to align the Y direction position (level) of the lower surface of the N+ type region 140 and the Y direction position (level) of the upper surface of the gate electrode 160 substantially at the same position, which may solve the channel non-formation problem.

In addition, an X direction maximum length of the upper portion 142-1 of the second N+ type region 142 is determined by an X direction length of the opening exposed by the hardmask 220, but an X direction maximum length of the lower portion 142-2 of the second N+ type region 142 is determined by an ion implantable distance from the exposed side surface of the trench 210. Accordingly, the upper and lower portions 142-1 and 142-2 of the second N+ type region 142 may have a different X direction maximum length from one side surface of the trench 210, that is, a different X direction width each other, for example, the upper portion 142-1 of the second N+ type region 142 may have a larger X direction maximum length from one side surface of the trench 210 than the lower portion 142-2 of the second N+ type region 142.

For example, the N type ions implantation may be performed by using a tilt ion implantation method. The tilt ion implantation (left, right) method may smoothly implant ions into the exposed side surface of the trench 210.

Subsequently, after removing the hardmask 220, the first to third upper gate insulation layers 155, 156, and 157 are formed on the gate electrode 160, and the source electrode 170 is formed on the P type region 130, on the N+ type region 140, and/or on the N− type layer 120. The source electrode 170 is insulated from the gate electrode 160 by the first to third upper gate insulation layers 155, 156, and 157.

Lastly, the drain electrode 180 is formed under the N+ type substrate 110 in the Y direction to manufacture the semiconductor device 100 shown in FIG. 1.

While embodiments of this invention have been described in connection with what is presently considered to be practical example embodiments, it is to be understood that the embodiments of the invention are not limited to the disclosed embodiments. On the contrary, they are intended to cover various modifications and equivalent arrangements included within the spirit and scope of the appended claims.

The following reference identifiers may be used in connection with the drawings to describe various features of embodiments of the present invention.
100: semiconductor device
110: N+ type substrate
120: N− type layer
130: P type region
135: P type shield region
136: asymmetric P type region
137: P+ type layer
140: N+ type region
141, 142, 143: first to third N+ type region
142-1: upper portion of the second N+ type region
142-2: lower portion of the second N+ type region
150: gate insulation layer
151, 152, 153: first to third lower gate insulation layers
155, 156, 157: first to third upper gate insulation layers
160: gate electrode
161, 162, 163: first to third gate electrodes
160P: preliminary gate electrode layer
170: source electrode
171: emitter electrode
180: drain electrode
181: collector electrode
210: trench
220: hardmask

What is claimed is:

1. A semiconductor device comprising:
an N+ type substrate;
an N− type layer disposed on the N+ type substrate in a first direction and having a trench opening upward in the first direction;
a P type region disposed within the N− type layer and disposed on a side of the trench;
an N+ type region disposed within the P type region and disposed on the side of the trench;
a gate electrode disposed within the trench, the gate electrode comprising a first gate electrode having an upper surface that is lower than an upper surface of the P type region in the first direction and a second gate electrode having an upper surface that is lower than the upper surface of the first gate electrode in the first direction; and
a source electrode and a drain electrode insulated from the gate electrode; and
wherein the N+ type region comprises:
a first N+ type region disposed on a side of the first gate electrode and having a lower surface that is lower than the upper surface of the first gate electrode in the first direction, and
a second N+ type region disposed on a side of the second gate electrode and having a lower surface that is lower than the lower surface of the first N+ type region in the first direction.

2. The semiconductor device of claim 1, wherein the lower surface of the second N+ type region is substantially at a same height as the upper surface of the second gate electrode in the first direction.

3. The semiconductor device of claim 1, wherein the lower surface of the second N+ type region is lower than the upper surface of the second gate electrode in the first direction.

4. The semiconductor device of claim 1, wherein:
the trench has side surfaces extending in a second direction perpendicular to the first direction and facing each other in a third direction perpendicular to the first direction and different from the second direction; and
the second N+ type region has an upper portion and a lower portion having different maximum lengths in the third direction from one side of the trench.

5. The semiconductor device of claim 4, wherein the upper portion of the second N+ type region has a greater maximum length in the third direction from the one side of the trench than the lower portion of the second N+ type region.

6. The semiconductor device of claim 4, wherein the upper portion of the second N+ type region is disposed on the lower portion of the second N+ type region in the first direction.

7. The semiconductor device of claim 1, wherein the gate electrode further comprises a third gate electrode having an upper surface at substantially a same level in the first direction as the upper surface of the P type region.

8. The semiconductor device of claim 7, wherein the N+ type region further comprises a third N+ type region disposed on a side of the third gate electrode and having a lower surface that is lower than the upper surface of the first gate electrode in the first direction.

9. The semiconductor device of claim 1, wherein the N− type layer further comprises a P type shield region surrounding a lower surface and both lower edges of the trench.

10. The semiconductor device of claim 1, wherein the N− type layer further comprises an asymmetric P type region surrounding a first lower edge and a first side of the trench and connected to the P type region.

11. The semiconductor device of claim 10, wherein:
the asymmetric P type region surrounds a portion of a lower surface of the trench; and
the asymmetric P type region does not surround a second lower edge of the trench or a second side of the trench.

12. A semiconductor device comprising:
an N− type layer having a trench opening upward in a first direction;
a P type region disposed within the N− type layer and disposed on a side of the trench,
an N+ type region disposed within the P type region and disposed on the side of the trench;
a gate electrode disposed within the trench, wherein the gate electrode comprises a first gate electrode having an upper surface that is lower than an upper surface of the P type region in the first direction and a second gate electrode having an upper surface that is lower than the upper surface of the first gate electrode in the first direction;
an emitter electrode and a collector electrode insulated from the gate electrode; and
a P+ type layer disposed between the N− type layer and the collector electrode; and
wherein the N+ type region comprises:
a first N+ type region disposed on a side of the first gate electrode and having a lower surface that is lower than the upper surface of the first gate electrode in the first direction; and
a second N+ type region disposed on a side of the second gate electrode and having a lower surface that is lower than the lower surface of the first N+ type region in the first direction.

13. The semiconductor device of claim 12, wherein the gate electrode further comprises a third gate electrode having an upper surface at substantially a same level in the first direction as the upper surface of the P type region.

14. The semiconductor device of claim 13, wherein the N+ type region further comprises a third N+ type region disposed on a side of the third gate electrode and having a lower surface that is lower than the upper surface of the first gate electrode in the first direction.

15. The semiconductor device of claim 12, wherein the N− type layer further comprises a P type shield region surrounding a lower surface and both lower edges of the trench.

16. The semiconductor device of claim 12, wherein the N− type layer further comprises an asymmetric P type region surrounding a first lower edge and a first side of the trench and connected to the P type region.

17. The semiconductor device of claim 16, wherein:
the asymmetric P type region surrounds a portion of a lower surface of the trench; and
the asymmetric P type region does not surround a second lower edge of the trench or a second side of the trench.

18. A method of manufacturing a semiconductor device, the method comprising:
forming an N− type layer on an upper surface of an N− type substrate in a first direction;
forming a P type region in the N− type layer;
etching the N− type layer to penetrate the P type region to form a trench;
filling the trench with a preliminary gate electrode layer;
over-etching the preliminary gate electrode layer until an upper surface of the preliminary gate electrode layer is lower than an upper surface of the P type region in the first direction to form a gate electrode and to expose a portion of a side surface of the trench;
implanting N type ions into the upper surface of the P type region disposed adjacent to the trench and the exposed portion of the side surface of the trench to form an N+ type region; and
forming a source electrode and a drain electrode to be insulated from the gate electrode.

19. The method of claim 18, wherein implanting the N type ions into the upper surface of the P type region disposed adjacent to the trench and the exposed portion of the side surface of the trench to form the N+ type region is performed after forming a hardmask on the P type region exposing the upper surface of the P type region disposed adjacent to the trench.

20. The method of claim 18, wherein implanting the N type ions into the upper surface of the P type region disposed adjacent to the trench and the exposed portion of the side surface of the trench to form the N+ type region is performed using a tilt ion implantation method.
